(19) United States
(12) Patent Application Publication
(10) Pub. No.: US 2015/0316614 A1
(43) Pub. Date: Nov. 5, 2015

(54) DEBUGGING SYSTEM AND METHOD

(71) Applicant: XCERRA CORPORATION, NORWOOD, MA (US)

(72) Inventors: TODOR K. PETROV, MANSFIELD, MA (US); IAN HARRISON, NORFOLK, MA (US)

(21) Appl. No.: 14/702,012

(22) Filed: May 1, 2015

Related U.S. Application Data
(60) Provisional application No. 61/987,741, filed on May 2, 2014.

(51) Int. Cl. G01R 31/317; G01R 31/28

(52) U.S. Cl. CPC G01R 31/31705; G01R 31/2834

(57) ABSTRACT

A method, computer program product, and computing system for monitoring a first group of signals present on a first group of conductive paths within a debugging coupler that is configured to be releasably electrically coupleable to a test head of an automated test platform while executing at least a portion of an automated test process on the automated test platform. A second group of signals present on a second group of conductive paths is monitored while executing the at least a portion of the automated test process on the automated test platform. The first group of signals and the second group of signals are temporally aligned, thus defining a group of temporally aligned signals.

### RELATED APPLICATION

This application claims the benefit of U.S. Provisional Application No. 61/987,741, filed on 2 May 2014 and entitled “SYSTEM AND METHOD FOR AUTOMATED TESTING”.

### TECHNICAL FIELD

This disclosure relates to automated debugging equipment and, more particularly, to automated debugging equipment that monitors signals to numerous test points of a Device Under Test (DUT).

### BACKGROUND

Automated test equipment systems may be used to test various electronic components, which are often referred to as DUTs. Such systems may automate the testing of such components, wherein a component may be subjected to a battery of different tests in some form of logical fashion. Additionally, such systems may provide further levels of automation, wherein the components being tested may be subjected to automated testing procedures, wherein measurements are taken at various test points of the DUT. Further, additional automation may be provided, wherein DUTs are automatically swapped out (upon completion of a testing procedure) and replaced with a component that is yet to be tested.

### SUMMARY OF DISCLOSURE

In one implementation, a computer-implemented method is executed on a computing device. The computer-implemented method includes monitoring a first group of signals present on a first group of conductive paths within a debugging coupler that is configured to be releasably electrically coupleable to a test head of an automated test platform while executing at least a portion of an automated test process on the automated test platform. A second group of signals present on a second group of conductive paths is monitored while executing the at least a portion of the automated test process on the automated test platform. The first group of signals and the second group of signals are temporally aligned, thus defining a group of temporally aligned signals.

One or more of the following features may be included. A temporally-synchronized report may be generated that includes the group of temporally aligned signals. Monitoring a first group of signals present on a first group of conductive paths may include monitoring a synchronization signal while monitoring a first group of signals present on a first group of conductive paths. Monitoring a second group of signals present on a second group of conductive paths may include monitoring the synchronization signal while monitoring the second group of signals present on the second group of conductive paths. Temporally aligning the first group of signals and the second group of signals may include temporally aligning the first group of signals and the second group of signals based, at least in part, upon the synchronization signal. The synchronization signal may be generated by a signal generator included within a debugging system configured to debug an automated test process used on an automated test platform. The synchronization signal may be obtained from a conductive path included within the debugging coupler.

In another implementation, a computer program product resides on a computer readable medium that has a plurality of instructions stored on it. When executed by a processor, the instructions cause the processor to perform operations including monitoring a first group of signals present on a first group of conductive paths within a debugging coupler that is configured to be releasably electrically coupleable to a test head of an automated test platform while executing at least a portion of an automated test process on the automated test platform. A second group of signals present on a second group of conductive paths is monitored while executing the at least a portion of the automated test process on the automated test platform. The first group of signals and the second group of signals are temporally aligned, thus defining a group of temporally aligned signals.

One or more of the following features may be included. A temporally-synchronized report may be generated that includes the group of temporally aligned signals. Monitoring a first group of signals present on a first group of conductive paths may include monitoring a synchronization signal while monitoring a first group of signals present on a first group of conductive paths. Monitoring a second group of signals present on a second group of conductive paths may include monitoring the synchronization signal while monitoring the second group of signals present on the second group of conductive paths. Temporally aligning the first group of signals and the second group of signals may include temporally aligning the first group of signals and the second group of signals based, at least in part, upon the synchronization signal. The synchronization signal may be generated by a signal generator included within a debugging system configured to debug an automated test process used on an automated test platform. The synchronization signal may be obtained from a conductive path included within the debugging coupler.

In another implementation, a computing system includes at least one processor and at least one memory architecture coupled with the at least one processor, wherein the computing system is configured to perform operations including monitoring a first group of signals present on a first group of conductive paths within a debugging coupler that is configured to be releasably electrically coupleable to a test head of an automated test platform while executing at least a portion of an automated test process on the automated test platform. A second group of signals present on a second group of conductive paths is monitored while executing the at least a portion of the automated test process on the automated test platform. The first group of signals and the second group of signals are temporally aligned, thus defining a group of temporally aligned signals.

One or more of the following features may be included. A temporally-synchronized report may be generated that includes the group of temporally aligned signals. Monitoring a first group of signals present on a first group of conductive paths may include monitoring a synchronization signal while monitoring a first group of signals present on a first group of conductive paths. Monitoring a second group of signals present on a second group of conductive paths may include monitoring the synchronization signal while monitoring the second group of signals present on the second group of conductive paths. Temporally aligning the first group of signals and the second group of signals may include temporally aligning the first group of signals and the second group of signals based, at least in part, upon the synchronization signal. The synchronization signal may be generated by a signal generator included within a debugging system configured to debug an automated test process used on an automated test platform. The synchronization signal may be obtained from a conductive path included within the debugging coupler.

The details of one or more implementations are set forth in the accompanying drawings and the description below. Other features and advantages will become apparent from the description, the drawings, and the claims.

### BRIEF DESCRIPTION OF THE DRAWINGS

FIG. 1 is a diagrammatic view of an automated test platform;

FIG. 2 is diagrammatic view of the automated test platform of FIG. 1 including a debugging system;

FIG. 3 is a diagrammatic detail view of the debugging system of FIG. 3;

FIG. 4 is a flowchart of one implementation of a debugging process executed by the debugging system of FIG. 3;

FIG. 5 is a flowchart of another implementation of a debugging process executed by the debugging system of FIG. 3;

FIG. 6 is a flowchart of another implementation of a debugging process executed by the debugging system of FIG. 3; and

FIG. 7 is a diagrammatic view of a report generated by the debugging system of FIG. 3.

Like reference symbols in the various drawings indicate like elements.

### DETAILED DESCRIPTION OF THE PREFERRED EMBODIMENTS

### System Overview:

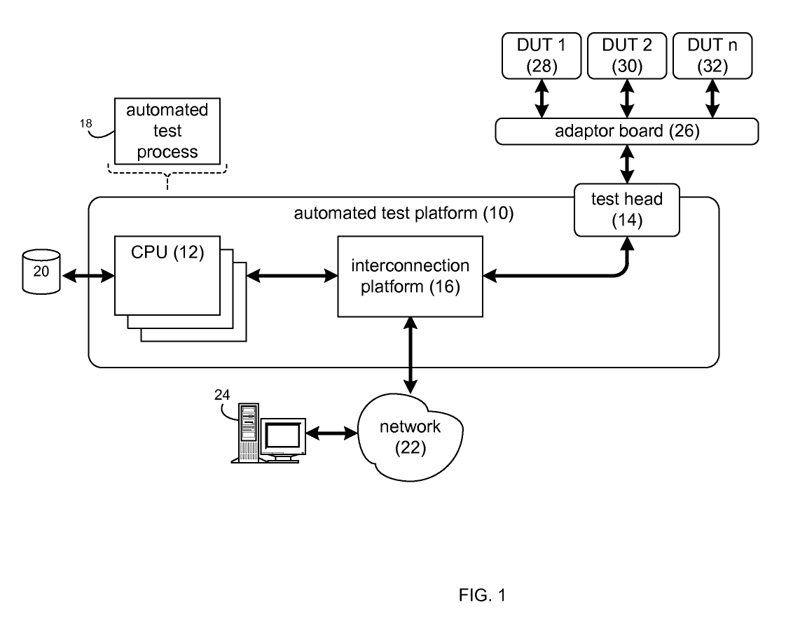

Referring to FIG. 1, there is shown automated test platform 10. Examples of automated test platform 10 may include, but are not limited to, systems that automate the verification and validation of devices under test (DUTs). As discussed above, automated test equipment systems (e.g. automated test platform 10) may be used to test various electronic components in an automated fashion. Typically, the devices under test are subjected to a battery of different tests, wherein the testing procedures are automated in a logical fashion. For example, during the testing of a power supply, the power supply may be subjected to varying voltage levels and varying voltage frequencies. Further, during the testing of a noise canceling circuit, such a circuit may be subjected to varying levels and frequencies of noise to confirm the satisfactory performance of the same.

Automated test platform 10 may include one or more central processing units (e.g. CPU subsystem 12) and one or more test heads (e.g. test head 14), which may be coupled together via interconnection platform 16 (e.g., a PCIe bus or a USB bus). If configured as a PCIe bus, interconnection platform 16 may allow for test head 14 and CPU subsystem 12 to communicate via interconnection platform 16 using the PCIe communication standards. As is known in the art, PCIe (Peripheral Component Interconnect Express) is a high-speed serial computer expansion bus standard designed to replace older bus systems (e.g., PCI, PCI-X, and AGP). Through the use of PCIe, higher maximum system bus throughput may be achieved. Other benefits may include lower I/O pin count, a smaller physical footprint, better performance-scaling for bus devices, a more detailed error detection and reporting mechanism, and native plug-n-play functionality. If configured as a USB bus, interconnection platform 16 may allow for test head 14 and CPU subsystem 12 to communicate via interconnection platform 16 using the USB communication standards. As is known in the art, Universal Serial Bus (USB) is an industry standard that defines the cables, connectors and communications protocols used in a bus for connection, communication, and power supply between computers and various electronic devices/components.

Examples of CPU subsystem 12 may include but are not limited to a personal computer, a server computer, a series of server computers, a mini computer or a single-board computer. CPU subsystem 12 may execute one or more operating systems, examples of which may include but are not limited to: Microsoft Windows Server™; Redhat Linux™, Unix, or a custom operating system, for example.

While in this particular example, automated test platform 10 is shown to include three CPU subsystems, this is for illustrative purposes only and is not intended to be a limitation of this disclosure, as other configurations are possible. For example, the number of CPU subsystems utilized within automated test platform 10 may be increased or decreased depending upon the anticipated loading of automated test platform 10.

CPU subsystem 12 may execute one or more automated test programs (e.g. automated test process 18), wherein automated test process 18 may be configured to automate the testing of various devices under test. Through the use of automated test process 18, an administrator (not shown) of automated test platform 10 may define and execute testing procedures/routines for the various devices under test.

The instruction sets and subroutines of automated test process 18, which may be stored on storage device 20 coupled to/included within CPU subsystem 12, may be executed by one or more processors (not shown) and one or more memory architectures (not shown) included within CPU subsystem 12. Storage device 20 may include but is not limited to: a hard disk drive; a tape drive; an optical drive; a RAID device; a random access memory (RAM); a read-only memory (ROM); and all forms of flash memory storage devices.

CPU subsystem 12 may be connected to one or more networks (e.g., network 22), examples of which may include but are not limited to: a local area network, a wide area network, an intranet or the internet, for example. Accordingly, CPU subsystem 12 may be administered and/or controlled via network 22. Therefore, an administrator (not shown) may use a remote computer (e.g., remote computer 24) coupled to network 22 to define and/or administer various testing procedures and/or routines via automated test process 18.

Automated test platform 10 may be configured to work with adapter board 26. wherein adapter board 26 may be configured to adapt test head 14 (which may be universal) to the particular type of device under test. For example, test head 14 may be a universal connector assembly that is configured to provide signals to and/or read signal from the device under test. Specifically, automated test platform 10 and/or automated test process 18 may be configured to e.g., provide one or more signals to the device under test and read the signals present at various test points of the device under test during these procedures.

In this particular example, adapter board 26 is shown being configured to accommodate a plurality of devices under test, namely devices under test 28, 30, 32 (representing DUTs 1-n). However, this is for illustrative purposes only. For example, the number of devices under test may be increased or decreased depending upon the design criteria of adapter board 26, automated test platform 10 and/or automated test process 18. Alternatively, test head 14 may be configured to work without adapter board 26, wherein test head 14 may be configured to allow a single device under test (e.g., device under test 28) to directly plug into/couple with test head 14.

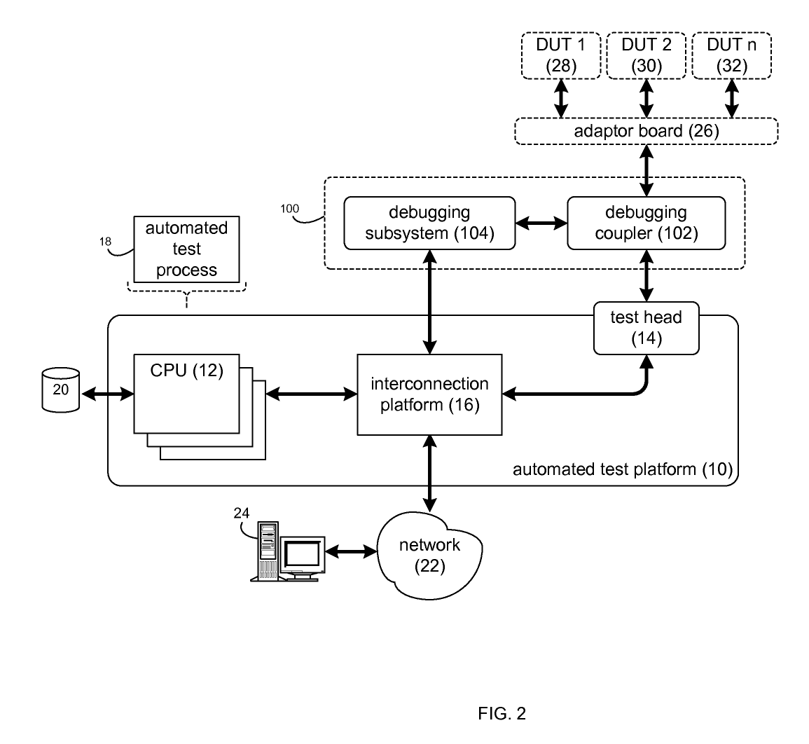

Referring also to FIG. 2, there is shown debugging system 100 for use with automated test platform 10. As discussed above, CPU subsystem 12 within automated test platform 10 may execute one or more automated test programs (e.g. automated test process 18), wherein automated test process 18 may be configured to automate the testing of various devices under test. When designing such automated test programs (e.g. automated test process 18), these test programs (e.g. automated test process 18) often need to be debugged and/or verified prior to actual use.

While the following example and discussion concern debugging system 100 as being a stand-alone system that is designed to work in conjunction with automated test platform 10, this is for illustrative purposes only and is not intended to be a limitation of this disclosure, as other configurations are possible. For example, some or all of debugging system 100 may be incorporated into and/or included within automated test platform 10. For example, automated test platform 10 may be configured to include one or more signal monitoring systems to monitor signals present within e.g., devices under test 28, 30, 32. Additionally/alternatively, automated test platform 10 may be configured to include one or more signal generation systems to provide signals to e.g., devices under test 28, 30, 32. Accordingly, these signal monitoring systems and/or signal generation systems included within automated test platform 10 may be utilized by debugging system 100 to effectuate some or all of the functionality of debugging system 100.

In this particular embodiment of debugging system 100, debugging system 100 is shown to include debugging coupler 102 and debugging subsystem 104. Debugging coupler 102 may be configured to be releasably electrically coupleable to test head 14. Further, debugging coupler 102 may also be configured to be releasably electrically coupleable to adapter board 26. Accordingly and as shown in FIG. 2, debugging coupler 102 may be configured to be positioned between test head 14 and adapter board 26, thus allowing any signals applied to (or read from) adapter board 26 by automated test platform 10/automated test process 18 to pass through debugging coupler 102.

As discussed above, test head 14 may be configured to work without adapter board 26, wherein test head 14 may be configured to allow a single device under test (e.g., device under test 28) to directly plug into/couple with test head 14. Accordingly and in such an embodiment, debugging coupler 102 may be configured to be releasably electrically coupleable to test head 14 and be releasably electrically coupleable to a device under test (e.g., device under test 28). Accordingly, debugging coupler 102 may be configured to be positioned between test head 14 and a device under test (e.g., device under test 28), thus allowing any signals applied to (or read from) the device under test (e.g., device under test 28) by automated test platform 10/automated test process 18 to pass through debugging coupler 102.

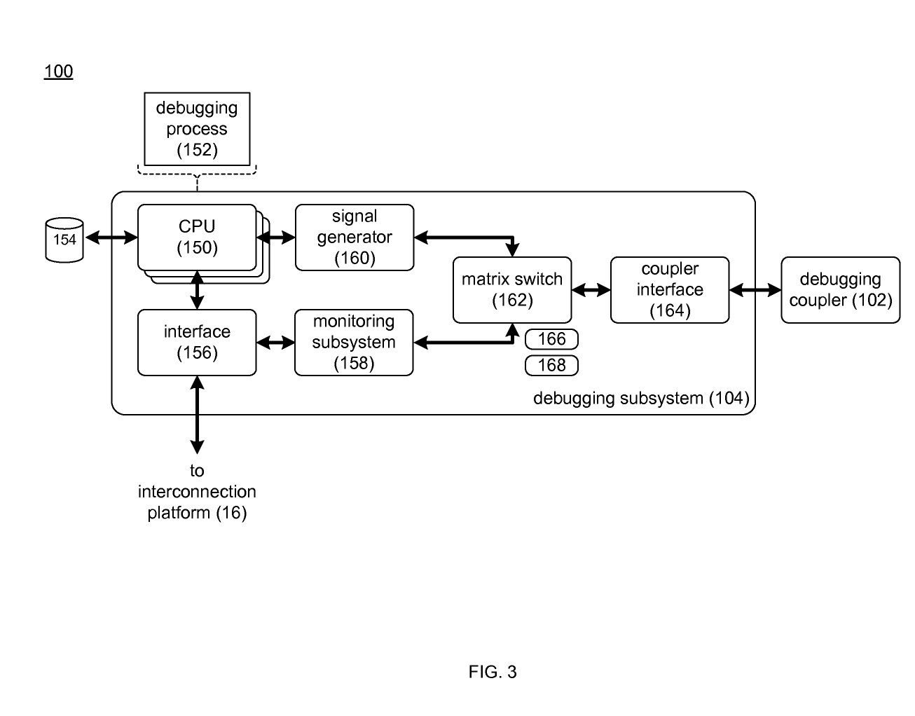

Referring also to FIG. 3, a detail view of debugging system 100 is shown. Specifically, debugging subsystem 104 is shown to include one or more central processing units (e.g. CPU subsystem 150). Examples of CPU subsystem 150 may include but are not limited to a personal computer, a server computer, a series of server computers, a mini computer or a single-board computer. CPU subsystem 12 may execute one or more operating systems, examples of which may include but are not limited to: Microsoft Windows Server™; Redhat Linux™, Unix, or a custom operating system, for example.

While in this particular example, debugging subsystem 104 of debugging system 100 is shown to include three CPU subsystems, this is for illustrative purposes only and is not intended to be a limitation of this disclosure, as other configurations are possible. For example, the number of CPU subsystems utilized within debugging subsystem 104 of debugging system 100 may be increased or decreased depending upon the anticipated loading of debugging system 100.

CPU subsystem 150 may execute one or more debugging programs (e.g., debugging process 152) which be configured to work with/interact with the automated test programs (e.g. automated test process 18). Debugging process 152 may be configured to automate the debugging of the automated test programs (e.g. automated test process 18). Through the use of debugging process 152, an administrator (not shown) of automated test platform 10 may define and execute (e.g., using remote computer 24) debugging procedures/routines (e.g. debugging process 152) for the automated test programs (e.g. automated test process 18).

The instruction sets and subroutines of debugging process 152, which may be stored on storage device 154 coupled to/included within CPU subsystem 150, may be executed by one or more processors (not shown) and one or more memory architectures (not shown) included within CPU subsystem 150. Storage device 154 may include but is not limited to: a hard disk drive; a tape drive; an optical drive; a RAID device; a random access memory (RAM); a read-only memory (ROM); and all forms of flash memory storage devices.

CPU subsystem 150 may be connected (directly or indirectly) to one or more networks (e.g., network 22), examples of which may include but are not limited to: a local area network, a wide area network, an intranet or the internet, for example. Accordingly, CPU subsystem 12 may be administered and/or controlled via network 22. Therefore, an administrator (not shown) may use a remote computer (e.g., remote computer 24) coupled to network 22 to define and/or administer various debugging procedures and/or routines via debugging process 152.

As discussed above, the various components of automated test platform 10 may be coupled together via interconnection platform 16 (e.g., a PCIe bus or a USB bus). Accordingly, debugging subsystem 104 may include interface 156 for interfacing debugging system 100 with automated test platform 10.

Debugging subsystem 104 of debugging system 100 may include various systems/subsystems/components that provide various levels of functionality to debugging system 100. Debugging subsystem 104 of debugging system 100 may include monitoring subsystem 158 and signal generator 160, which may be coupled to matrix switch 162. The output of matrix switch 162 may be provided to coupler interface 164, which may be configured to interface debugging subsystem 104 with debugging coupler 102. While monitoring subsystem 158, signal generator 160, and matrix switch 162 are shown to be included within debugging subsystem 104 of debugging system 100, this is for illustrative purposes only and in not intended to be a limitation of this disclosure, as other configurations are possible and are considered to be within the scope of this disclosure. For example, one or more of monitoring subsystem 158, signal generator 160, and matrix switch 162 may be included within debugging coupler 102.

As discussed above, debugging coupler 102 may be configured to be positioned between test head 14 and adaptor board 26/device under test 28, thus allowing any signals applied to (or read from) adaptor board 26/device under test 28 by automated test platform 10/automated test process 18 to pass through debugging coupler 102. Accordingly and through the use of monitoring subsystem 158 and matrix switch 162, any of these signals applied to (or read from) adaptor board 26/device under test 28 may be monitored by debugging system 100.

For illustrative purposes only, assume that monitoring subsystem 158 includes a multi-channel analog or digital oscilloscope. One such example may include a four channel analog oscilloscope that is capable of simultaneously monitoring four of the above-described signals, as well as having an input for a trigger (i.e., synchronization) signal. Other examples may include but are not limited to logic analyzers, digital multi-meters, data acquisition systems, and waveform digitizers. Further, assume that debugging coupler 102 includes e.g., ninety-six conductive paths for routing signals from test head 14 to adaptor board 26/device under test 28. Accordingly and in such a configuration, matrix switch 162 may be a four by ninety-six matrix switch that is capable of coupling any of the four oscilloscope channels to any of the ninety-six conductive paths within debugging coupler 102, thus allowing for the monitoring of any of the ninety-six signals present on the ninety-six conductive paths of debugging coupler 102. Accordingly, by properly configuring matrix switch 162 (which may be controllable/configurable by CPU subsystem 150/debugging process 152), any four of the ninety-six conductive paths within debugging coupler 102 may be simultaneously monitored by debugging system 100 via monitoring subsystem 158, thus indicating the type, amplitude and quality of the signals being applied to (or read from) adaptor board 26/device under test 28 by automated test platform 10. Accordingly and as will be discussed below in greater detail, debugging system 100 may allow the user of automated test platform 10 to confirm the proper operation of automated test platform 10 and the above-described automated test programs (e.g. automated test process 18).

As discussed above, debugging subsystem 104 of debugging system 100 may also include signal generator 160, which may also be coupled to matrix switch 162. Unlike monitoring subsystem 158 that monitors the signals present on (in the example) any four of the ninety-six conductive paths within debugging coupler 102, signal generator 160 may be configured to apply one or more signals to any of the ninety-six conductive paths within debugging coupler 102. Assume for illustrative purposes that signal generator 160 is also a four channel signal generator that is capable of generating four separate and distinct waveforms that may be applied to (in this example) the ninety-six conductive paths within debugging coupler 102. Accordingly and in such a configuration where signal generator 160 is included within debugging subsystem 104, matrix switch 162 may be an eight by ninety-six matrix switch, wherein a first group of four inputs (of the eight inputs) may be utilized by monitoring subsystem 158 and a second group of four inputs (of the eight inputs) may be utilized by signal generator 160. Accordingly, signal generator 160 in combinations with matrix switch 162 may be capable of coupling any of the four channels of signal generator 160 to any of the ninety-six conductive paths within debugging coupler 102. Examples of the types of waveforms that may be applied to the conductive paths within debugging coupler 102 may include but are not limited to AC waveforms, DC waveforms, sinewaves, square waves, saw tooth waveforms, triangular waveforms, ramp waveforms, DC pulse waveforms, complex waveforms, arbitrary waveforms and impulse functions.

Accordingly and through the use of signal generator 160, debugging system 100 may be configured to emulate a device under test, even though the device under test is not yet available for testing. Specifically and through the use of a design specification and/or computer simulations associated with the device under test, debugging system 100 may be configured/programmed (via CPU subsystem 150/debugging process 152) to emulate the device under test, even before a physical device under test is available for testing so that automated test process 18 may be debugged.

For example, if the design specification and/or computer simulations of a not-yet-released device under test indicate that the device under test (when available) would e.g., generate a three volt sinusoid on conductive path fifty-seven of debugging coupler 102 whenever e.g., a binary one is present on conductive path fifty-six of debugging coupler 102, CPU subsystem 150/debugging process 152 may be e.g., programmed/configured to monitor (via monitoring subsystem 158) the signal present on conductive path fifty-six of debugging coupler 102 and provide (via signal generator 160) the three volt sinusoid on conductive path fifty-seven of debugging coupler 102 whenever a binary one is present on conductive path fifty-six of debugging coupler 102. Accordingly, debugging system 100 may allow for the debugging of automated test process 18 prior to the device under test actually being available for automated testing by automated test process 18. Accordingly and through the use of debugging system 100, lead time may be reduced, since automated test process 18 may be debugged by debugging system 100 prior to the availability of the device under test for which automated test process 18 was designed, thus allowing for quicker automated testing of the device under test upon it being available (as automated test process 18 was previously debugged).

### Debugging Process

As discussed above, debugging process 152 may be configured to automate the debugging of the automated test programs (e.g. automated test process 18). Through the use of debugging process 152, an administrator (not shown) of automated test platform 10 may define and execute (e.g., using remote computer 24) debugging procedures/routines (e.g. debugging process 152) for the automated test programs (e.g. automated test process 18).

As discussed above, debugging coupler 102 may include a plurality of conductive paths for routing signals from test head 14 to adaptor board 26/device under test 28. For the following discussion, assume that debugging coupler 102 includes ninety-six conductive paths for routing signals from test head 14 to adaptor board 26/device under test 28. Further assume for the following discussion that monitoring subsystem 158 is a four channel device that is capable of simultaneously monitoring the signals present on four conductive paths within debugging coupler 102.

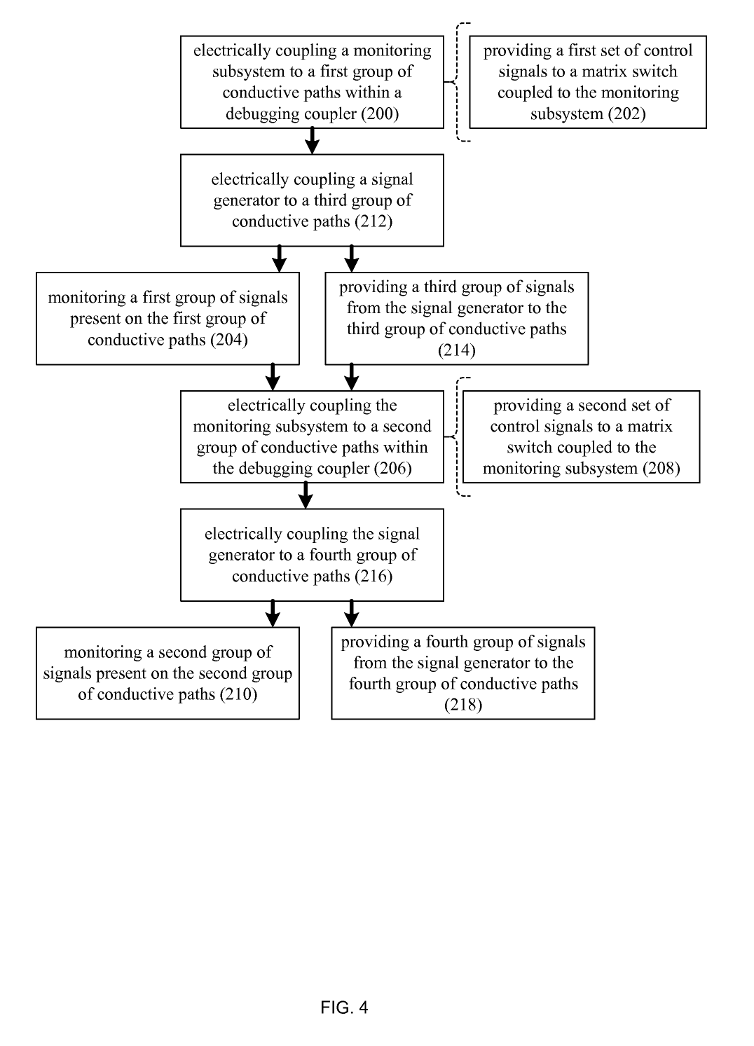

Referring also to FIG. 4, debugging process 152 may electrically couple 200 monitoring subsystem 158 to a first group of conductive paths (e.g., conductive paths 1-4 of the ninety-six paths discussed above) within debugging coupler 102. As discussed above, debugging coupler 102 may be configured to be releasably electrically coupleable to test head 14 of automated test platform 10.

When electrically coupling 200 monitoring subsystem 158 to the first group of conductive paths (e.g., conductive paths 1-4 of the ninety-six paths discussed above) within debugging coupler 102, debugging process 152 may provide 202 a first set of control signals (e.g., control signals 166) to matrix switch 162 coupled to monitoring subsystem 158. Control signals 166 may adjust matrix switch 162 to allow for monitoring of conductive paths 1-4.

Debugging process 152 may monitor 204 a first group of signals present on the first group of conductive paths (e.g., conductive paths 1-4 of the ninety-six paths discussed above) while executing at least a portion of automated test process 18 on automated test platform 10. For example, all or a portion of automated test process 18 may be executed on automated test platform 10 and, during this execution, debugging process 152 may monitor 204 the signals present on conductive paths 1-4 of debugging coupler 102.

Once automated test process 18 (or a portion thereof) has been executed and debugging process 152 has monitored 204 the signals present on conductive paths 1-4 of debugging coupler 102, debugging process 152 may electrically couple 206 monitoring subsystem 158 to a second group of conductive paths (e.g., conductive paths 5-8 of the ninety-six paths discussed above) within debugging coupler 102.

When electrically coupling 206 monitoring subsystem 158 to the second group of conductive paths (e.g., conductive paths 5-8 of the ninety-six paths discussed above) within debugging coupler 102, debugging process 152 may provide 208 a second set of control signals (e.g., control signals 168) to matrix switch 162 coupled to monitoring subsystem 158. Control signals 168 may adjust matrix switch 162 to allow for monitoring of conductive paths 5-8.

Debugging process 152 may monitor 210 a second group of signals present on the second group of conductive paths (e.g., conductive paths 5-8 of the ninety-six paths discussed above) while executing the at least a portion of the automated test process on the automated test platform. For example, all or a portion of automated test process 18 may be executed on automated test platform 10 and, during this execution, debugging process 152 may monitor 210 the signals present on conductive paths 5-8 of debugging coupler 102.

If the above-described processes are repeated (in this example) twenty-two additional times, the signals present on the remaining eighty-eight conductive paths (of the above-described ninety-six conductive paths included within debugging coupler 102) may be monitored, four conductive paths at a time.

As discussed above and through the use of signal generator 160, debugging system 100 may be configured to emulate a device under test, even though the device under test may not yet be available for testing. Accordingly and in the event that such emulation is desired/required, debugging process 152 may electrically couple 212 signal generator 160 to a third group of conductive paths (e.g., one or more of the ninety-six paths discussed above) within debugging coupler 102 while electrically coupling 200 monitoring subsystem 158 to the first group of conductive paths (e.g., conductive paths 1-4 of the ninety-six paths discussed above). Debugging process 152 may then provide 214 a third group of signals from signal generator 160 to the third group of conductive paths (e.g., one or more of the ninety-six paths discussed above) while monitoring 204 the first group of signals present on the first group of conductive paths (e.g., conductive paths 1-4 of the ninety-six paths discussed above). Debugging process 152 may provide 214 this third group of signals to emulate the type of signals that would be generated by the device under test if one were available.

Once automated test process 18 (or a portion thereof) has been executed and debugging process 152 has monitored 204 the signals present on conductive paths 1-4 of debugging coupler 102, debugging process 152 may electrically couple 216 signal generator 160 to a fourth group of conductive paths (e.g., one or more of the ninety-six paths discussed above) within debugging coupler 102 while electrically coupling 206 monitoring subsystem 158 to the second group of conductive paths (e.g., conductive paths 5-8 of the ninety-six paths discussed above). Debugging process 152 may then provide 218 a fourth group of signals from signal generator 160 to the fourth group of conductive paths (e.g., one or more of the ninety-six paths discussed above) while monitoring 210 a second group of signals present on the second group of conductive paths (e.g., conductive paths 5-8 of the ninety-six paths discussed above). Debugging process 152 may provide 218 this fourth group of signals to emulate the type of signals that would be generated by the device under test if one were available.

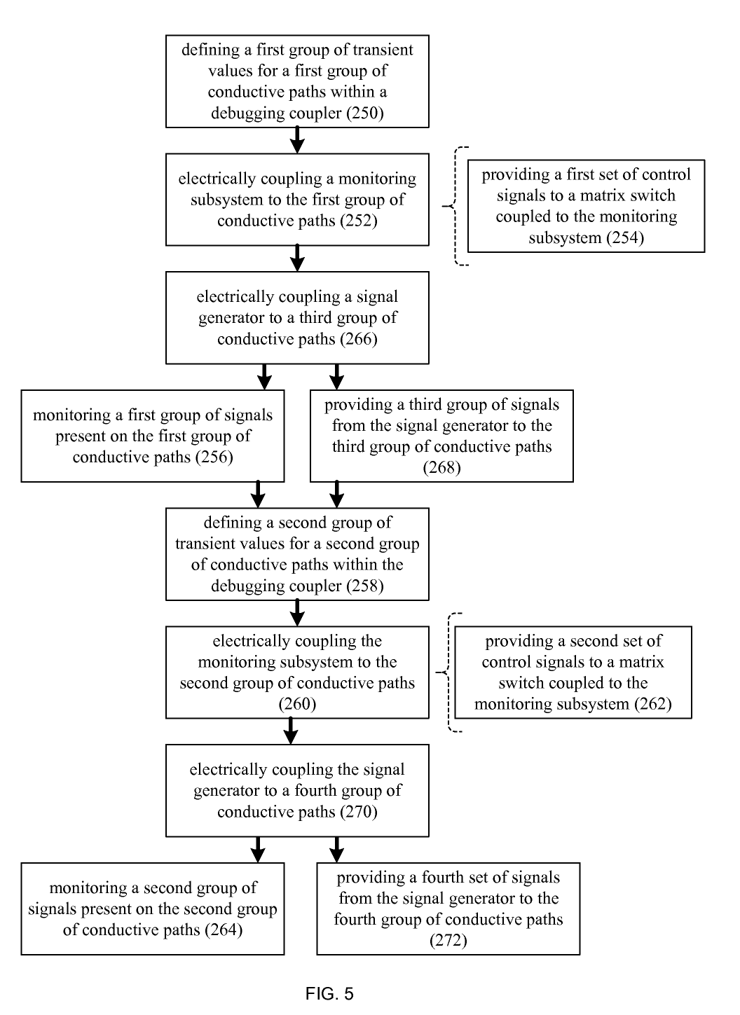

Referring also to FIG. 5, if transients (such as over voltage conditions) occur during the testing of a device under test, the device under test may be destroyed. What may be more concerning is if the device under test is not destroyed but is merely damaged. Accordingly, as it is not destroyed, it may pass any pass/fail tests administered by automated test process 18. However, as the device under test was damaged, the longevity and/or reliability of the device under test may be compromised. Such a situation may prove to be highly problematic for mission critical devices such as antilock brake system controllers.

Accordingly, debugging process 152 may define 250 a first group of transient values for a first group of conductive paths (e.g., conductive paths 1-4 of the ninety-six paths discussed above) within debugging coupler 102. This first group of transient values may define a first group of do-not-exceed values for the first group of conductive paths (e.g., conductive paths 1-4 of the ninety-six paths discussed above).

Assume for this example that these transient values are voltage levels that exceed six volts DC, where it is known that values that exceed six volts DC may damage the device under test, while values beneath this range cannot cause any damage. Accordingly and when debugging automated test process 18, debugging process 152 may monitor the amplitude of the signals present on the conductive paths within debugging coupler 102 to determine if they exceed this transient value of six volts DC. While in this example, all conductive paths are defined as having the same transient value, this is for illustrative purposes only and is not intended to be a limitation of this disclosure, as other configurations are possible. For example, each conductive path within debugging coupler 102 may have a unique transient value defined 250 by debugging process 152.

Debugging process 152 may electrically couple 252 monitoring subsystem 158 to the first group of conductive paths (e.g., conductive paths 1-4 of the ninety-six paths discussed above) within debugging coupler 102. When electrically coupling 252 monitoring subsystem 158 to the first group of conductive paths (e.g., conductive paths 1-4 of the ninety-six paths discussed above), debugging process 152 may provide 254 a first set of control signals (e.g., control signals 166) to matrix switch 162 coupled to monitoring subsystem 158. Control signals 166 may adjust matrix switch 162 to allow for monitoring of conductive paths 1-4.

Debugging process 152 may monitor 256 a first group of signals present on the first group of conductive paths (e.g., conductive paths 1-4 of the ninety-six paths discussed above) while executing at least a portion of automated test process 18 on automated test platform 10 to determine if any of the first group of signals exceeds any of the first group of transient values. For example, all or a portion of automated test process 18 may be executed on automated test platform 10 and, during this execution, debugging process 152 may monitor 256 the signals present on conductive paths 1-4 of debugging coupler 102 to determine if any of the first group of signals exceeds e.g., 6 volts DC.

As discussed above, while all conductive paths are defined as having the same transient value (e.g., 6 volts DC), this is for illustrative purposes only, as each conductive path within debugging coupler 102 may have a unique transient value defined 250 by debugging process 152.

Debugging process 152 may define 258 a second group of transient values for a second group of conductive paths (e.g., conductive paths 5-8 of the ninety-six paths discussed above) within debugging coupler 102. This second group of transient values may defines a second group of do-not-exceed values for the second group of conductive paths (e.g., conductive paths 5-8 of the ninety-six paths discussed above).

Assume for this illustrative example that the transient value for conductive paths 5-8 of the ninety-six paths discussed above is again defined 258 by debugging process 152 as 6 volts DC.

Debugging process 152 may electrically couple 260 monitoring subsystem 158 to the second group of conductive paths (e.g., conductive paths 5-8 of the ninety-six paths discussed above) within debugging coupler 102. When electrically coupling 260 monitoring subsystem 158 to the second group of conductive paths (e.g., conductive paths 5-8 of the ninety-six paths discussed above), debugging process 152 may provide 262 a second set of control signals (e.g., control signals 168) to matrix switch 162 coupled to monitoring subsystem 158. Control signals 168 may adjust matrix switch 162 to allow for monitoring of conductive paths 5-8.

Debugging process 152 may monitor 264 a second group of signals present on the second group of conductive paths (e.g., conductive paths 5-8 of the ninety-six paths discussed above) while executing at least a portion of automated test process 18 on automated test platform 10 to determine if any of the second group of signals exceeds any of the second group of transient values. For example, all or a portion of automated test process 18 may be executed on automated test platform 10 and, during this execution, debugging process 152 may monitor 264 the signals present on conductive paths 5-8 of debugging coupler 102 to determine if any of the second group of signals exceeds e.g., 6 volts DC.

As discussed above and through the use of signal generator 160, debugging system 100 may be configured to emulate a device under test, even though the device under test may not yet be available for testing. Accordingly and in the event that such emulation is desired/required, debugging process 152 may electrically couple 266 signal generator 160 to a third group of conductive paths (e.g., one or more of the ninety-six paths discussed above) within debugging coupler 102 while electrically coupling 252 monitoring subsystem 158 to the first group of conductive paths (e.g., conductive paths 1-4 of the ninety-six paths discussed above). Debugging process 152 may then provide 268 a third group of signals from signal generator 160 to the third group of conductive paths (e.g., one or more of the ninety-six paths discussed above) while monitoring 256 the first group of signals present on the first group of conductive paths (e.g., conductive paths 1-4 of the ninety-six paths discussed above) to determine if any of the first group of signals exceeds e.g., 6 volts DC. Debugging process 152 may provide 268 this third group of signals to emulate the type of signals that would be generated by the device under test if one were available.

Once automated test process 18 (or a portion thereof) has been executed and debugging process 152 has monitored 256 the signals present on conductive paths 1-4 of debugging coupler 102, debugging process 152 may electrically couple 270 signal generator 160 to a fourth group of conductive paths (e.g., one or more of the ninety-six paths discussed above) within debugging coupler 102 while electrically coupling 260 monitoring subsystem 158 to the second group of conductive paths (e.g., conductive paths 5-8 of the ninety-six paths discussed above). Debugging process 152 may then provide 272 a fourth group of signals from signal generator 160 to the fourth group of conductive paths (e.g., one or more of the ninety-six paths discussed above) while monitoring 264 a second group of signals present on the second group of conductive paths (e.g., conductive paths 5-8 of the ninety-six paths discussed above) to determine if any of the second group of signals exceeds e.g., 6 volts DC. Debugging process 152 may provide 272 this fourth group of signals to emulate the type of signals that would be generated by the device under test if one were available.

As discussed above, debugging process 152 in conjunction with automated test process 18 may systematically and sequentially monitor the various signals present on the conductive paths within debugging coupler 102. Accordingly, debugging process 10 may be configured to allow for the generation of temporally aligned reports, despite the fact that the signal levels present on the conductive paths were not monitored at the same time and were e.g., monitored four signals at a time for twenty-four discrete monitoring periods.

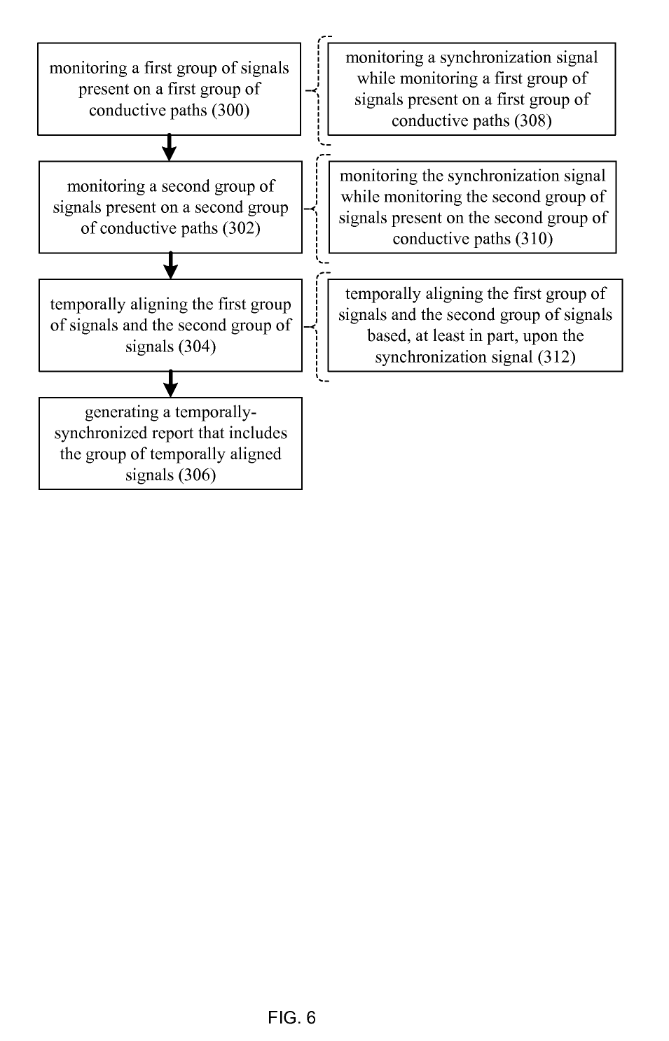

Referring also to FIG. 6, debugging process 152 may monitor 300 a first group of signals present on a first group of conductive paths (e.g., conductive paths 1-4 of the ninety-six paths discussed above) within debugging coupler 102 while executing at least a portion of automated test process 18 on automated test platform 10 and may monitor 302 a second group of signals present on a second group of conductive paths (e.g., conductive paths 5-8 of the ninety-six paths discussed above) while executing at least a portion of automated test process 18 on automated test platform 10. As discussed above, these monitoring processes may be repeated (in this example) twenty-two additional times so that the signals present on the remaining eighty-eight conductive paths (of the above-described ninety-six conductive paths included within debugging coupler 102) may be monitored by debugging process 152.

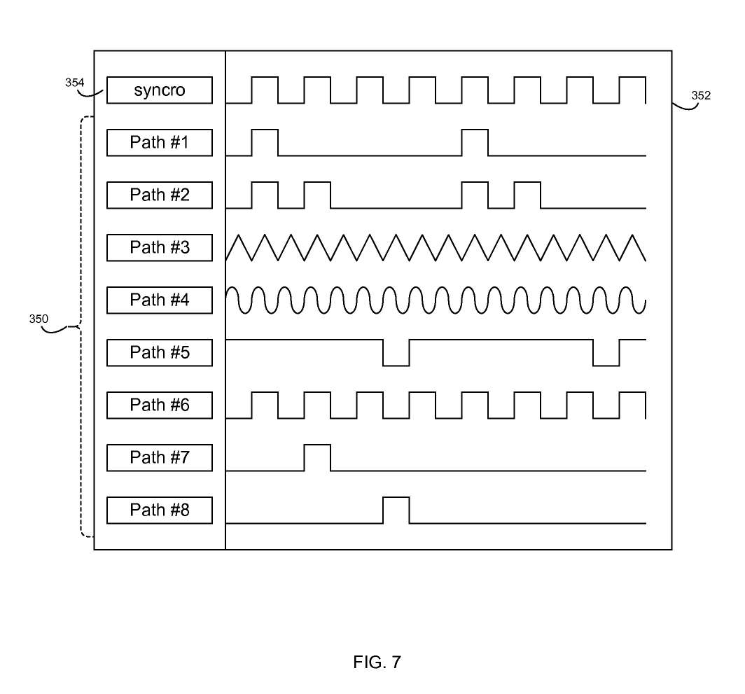

Referring also to FIG. 7 and continuing with the above-stated example in which a first group of signals are monitored 300 on conductive paths 1-4 (e.g., of the ninety-six paths discussed above) and a second group of signals are monitored 302 on conductive paths 5-8 (e.g., of the ninety-six paths discussed above), debugging process 152 may temporally align 304 the first group of signals (from conductive paths 1-4) and the second group of signals (from conductive paths 5-8), thus defining a group of temporally aligned signals (e.g., temporally aligned signals 350), wherein debugging process 152 may generate 306 temporally-synchronized report 352 that includes the group of temporally aligned signals (e.g., temporally aligned signals 350).

When monitoring 300 a first group of signals present on a first group of conductive paths (e.g., conductive paths 1-4 of the ninety-six paths discussed above) and monitoring 302 a second group of signals present on a second group of conductive paths (e.g., conductive paths 5-8 of the ninety-six paths discussed above), debugging process 152 may monitor 308 synchronization signal 354 while monitoring 300 the first group of signals present on a first group of conductive paths (e.g., conductive paths 1-4 of the ninety-six paths discussed above) and may monitor 310 synchronization signal 354 while monitoring 302 the second group of signals present on the second group of conductive paths (e.g., conductive paths 5-8 of the ninety-six paths discussed above).

When temporally aligning 304 the first group of signals (from conductive paths 1-4) and the second group of signals (from conductive paths 5-8), debugging process 152 may temporally align 312 the first group of signals and the second group of signals based, at least in part, upon synchronization signal 354. Synchronization signal 354 may be generated by signal generator 160 included within debugging system 100. Alternatively, synchronization signal 354 may be a signal (e.g., a clock signal) obtained from a conductive path included within debugging coupler 102.

### General:

As will be appreciated by one skilled in the art, the present disclosure may be embodied as a method, a system, or a computer program product. Accordingly, the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present disclosure may take the form of a computer program product on a computer-usable storage medium having computer-usable program code embodied in the medium.

Any suitable computer usable or computer readable medium may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium may include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. The computer-usable or computer-readable medium may also be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to the Internet, wireline, optical fiber cable, RF, etc.

Computer program code for carrying out operations of the present disclosure may be written in an object oriented programming language such as Java, Smalltalk, C++ or the like. However, the computer program code for carrying out operations of the present disclosure may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network/a wide area network/the Internet.

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, may be implemented by computer program instructions. These computer program instructions may be provided to a processor of a general purpose computer/special purpose computer/other programmable data processing apparatus, such that the instructions, which execute via the processor of the computer or other programmable data processing apparatus, create means for implementing the functions/acts specified in the flowchart and/or block diagram block or blocks.

These computer program instructions may also be stored in a computer-readable memory that may direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

The flowcharts and block diagrams in the figures may illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, may be implemented by special purpose hardware-based systems that perform the specified functions or acts, or combinations of special purpose hardware and computer instructions.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

A number of implementations have been described. Having thus described the disclosure of the present application in detail and by reference to embodiments thereof, it will be apparent that modifications and variations are possible without departing from the scope of the disclosure defined in the appended claims.

What is claimed is:

1. A computer-implemented method, executed on a computing device, the computer-implemented method comprising:
monitoring a first group of signals present on a first group of conductive paths within a debugging coupler that is configured to be releasably electrically coupleable to a test head of an automated test platform while executing at least a portion of an automated test process on the automated test platform;
monitoring a second group of signals present on a second group of conductive paths while executing the at least a portion of the automated test process on the automated test platform; and
temporally aligning the first group of signals and the second group of signals, thus defining a group of temporally aligned signals.

2. The computer-implemented method of claim 1 further comprising:
generating a temporally-synchronized report that includes the group of temporally aligned signals.

3. The computer-implemented method of claim 1 wherein monitoring a first group of signals present on a first group of conductive paths includes:
monitoring a synchronization signal while monitoring a first group of signals present on a first group of conductive paths.

4. The computer-implemented method of claim 3 wherein monitoring a second group of signals present on a second group of conductive paths includes:
monitoring the synchronization signal while monitoring the second group of signals present on the second group of conductive paths.

5. The computer-implemented method of claim 4 wherein temporally aligning the first group of signals and the second group of signals includes:
temporally aligning the first group of signals and the second group of signals based, at least in part, upon the synchronization signal.

6. The computer-implemented method of claim 1 wherein the synchronization signal is generated by a signal generator included within a debugging system configured to debug an automated test process used on an automated test platform.

7. The computer-implemented method of claim 1 wherein the synchronization signal is obtained from a conductive path included within the debugging coupler.

8. A computer program product residing on a computer readable medium having a plurality of instructions stored thereon which, when executed by a processor, cause the processor to perform operations comprising:
monitoring a first group of signals present on a first group of conductive paths within a debugging coupler that is configured to be releasably electrically coupleable to a test head of an automated test platform while executing at least a portion of an automated test process on the automated test platform;
monitoring a second group of signals present on a second group of conductive paths while executing the at least a portion of the automated test process on the automated test platform; and
temporally aligning the first group of signals and the second group of signals, thus defining a group of temporally aligned signals.

9. The computer program product of claim 8 further comprising instructions for:
generating a temporally-synchronized report that includes the group of temporally aligned signals.

10. The computer program product of claim 8 wherein monitoring a first group of signals present on a first group of conductive paths includes:
monitoring a synchronization signal while monitoring a first group of signals present on a first group of conductive paths.

11. The computer program product of claim 10 wherein monitoring a second group of signals present on a second group of conductive paths includes:
monitoring the synchronization signal while monitoring the second group of signals present on the second group of conductive paths.

12. The computer program product of claim 11 wherein temporally aligning the first group of signals and the second group of signals includes:
temporally aligning the first group of signals and the second group of signals based, at least in part, upon the synchronization signal.

13. The computer program product of claim 8 wherein the synchronization signal is generated by a signal generator included within a debugging system configured to debug an automated test process used on an automated test platform.

14. The computer program product of claim 8 wherein the synchronization signal is obtained from a conductive path included within the debugging coupler.

15. A computing system including a processor and memory configured to perform operations comprising:
monitoring a first group of signals present on a first group of conductive paths within a debugging coupler that is configured to be releasably electrically coupleable to a test head of an automated test platform while executing at least a portion of an automated test process on the automated test platform;
monitoring a second group of signals present on a second group of conductive paths while executing the at least a portion of the automated test process on the automated test platform; and
temporally aligning the first group of signals and the second group of signals, thus defining a group of temporally aligned signals.

16. The computing system of claim 15 further configured to perform operations comprising:
generating a temporally-synchronized report that includes the group of temporally aligned signals.

17. The computing system of claim 15 wherein monitoring a first group of signals present on a first group of conductive paths includes:
monitoring a synchronization signal while monitoring a first group of signals present on a first group of conductive paths.

18. The computing system of claim 17 wherein monitoring a second group of signals present on a second group of conductive paths includes:
monitoring the synchronization signal while monitoring the second group of signals present on the second group of conductive paths.

19. The computing system of claim 18 wherein temporally aligning the first group of signals and the second group of signals includes:
temporally aligning the first group of signals and the second group of signals based, at least in part, upon the synchronization signal.

20. The computing system of claim 15 wherein the synchronization signal is generated by a signal generator included within a debugging system configured to debug an automated test process used on an automated test platform.

21. The computing system of claim 15 wherein the synchronization signal is obtained from a conductive path included within the debugging coupler.
